(19) United States
(12) Patent Application Publication
(10) Pub. No.: US 2017/0288121 A1
(43) Pub. Date: Oct. 5, 2017

(54) ACOUSTIC RESONATOR INCLUDING COMPOSITE POLARITY PIEZOELECTRIC LAYER HAVING OPPOSITE POLARITIES

(71) Applicant: Avago Technologies General IP (Singapore) Pte. Ltd, Singapore (SG)

(72) Inventors: Dariusz Burak, Fort Collins, CO (US); Kevin J. Grannen, Thornton, CO (US)

(21) Appl. No.: 15/253,527

(22) Filed: Aug. 31, 2016

Related U.S. Application Data
(63) Continuation-in-part of application No. 15/086,397, filed on Mar. 31, 2016.

(51) Int. Cl. H01L 41/047; H01L 41/107

(52) U.S. Cl. CPC H01L 41/047; H01L 41/107

(57) ABSTRACT

A bulk acoustic wave (BAW) resonator device includes a bottom electrode disposed over a substrate and an acoustic reflector, a seed layer formed of a dielectric material disposed over the bottom electrode, a split piezoelectric layer disposed on the seed layer, and a top electrode disposed over the split piezoelectric layer. The split piezoelectric layer includes a first portion having a positive polarity due to the seed layer, a second portion having a negative polarity that is substantially opposite to the positive polarity of the first portion, and a metal interposer between the first portion and the second portion. The first portion of the piezoelectric layer has a first thickness and the second portion of the piezoelectric layer has a second thickness that is not equal to the first thickness, thereby lowering a coupling coefficient kt² of the BAW resonator device.

### CROSS-REFERENCE TO RELATED APPLICATIONS

This application is a continuation-in-part (CIP) application of application Ser. No. 15/086,397, filed on Mar. 31, 2016, which is hereby incorporated for all purposes.

### BACKGROUND

Acoustic transducers generally convert electrical signals to acoustic signals (sound waves) and convert received acoustic waves to electrical signals via inverse and direct piezoelectric effect. There are a number of types of acoustic transducers including acoustic resonators, such as bulk acoustic wave (BAW) resonators and surface acoustic wave (SAW) resonators. BAW resonators, in particular, include thin film bulk acoustic resonators (FBARs) and temperature-compensated FBARs (TC-FBARs), which generally have acoustic stacks formed over a substrate cavity, and solidly mounted resonators (SMRs), which generally have acoustic stacks formed over an acoustic mirror (e.g., a distributed Bragg reflector (DBR)). BAW resonators may be used for electrical filters and voltage transformers, for example, in a wide variety of electronic applications, such as cellular telephones, personal digital assistants (PDAs), electronic gaming devices, laptop computers and other portable communications devices.

Generally, a BAW resonator has an acoustic stack comprising a layer of piezoelectric layer between two conductive plates (e.g., top and bottom electrodes). The piezoelectric layer may be a thin film of various materials, such as aluminum nitride (AlN), zinc oxide (ZnO), or lead zirconate titanate (PZT), for example. Piezoelectric thin films made of AlN are advantageous since they generally maintain piezoelectric properties at high temperatures (e.g., above 400° C.). Indeed, BAW resonators have experienced mainstream adoption and success in wireless communications due in large part to the characteristics of thin film ALN piezoelectric layers. However, a BAW resonator including a piezoelectric layer formed of AlN has a resonance frequency limited to less than about 3 GHz, as a practical matter, in order to maintain acceptable device performance and reliability.

Thin film AlN is typically grown in a c-axis orientation perpendicular to a substrate surface using reactive magnetron sputtering. An AlN thin film may be deposited with various specific crystal orientations, including a wurtzite (0001) B4 structure, for example, which consists of a hexagonal crystal structure with alternating layers of aluminum (Al) and nitrogen (N). The piezoelectric nature of AlN stems from the c-axis orientation and the nature of the Al—N bonds of the AlN crystal lattice. That is, due to the nature of the Al—N bonding in the wurtzite structure, electric field polarization is present in the AlN crystal, resulting in the piezoelectric properties of the AlN thin film. To exploit this polarization and the corresponding piezoelectric effect, one must synthesize the AlN with a specific crystal orientation.

FIGS. 1A and 1B are perspective views of illustrative models of common wurtzite structures of piezoelectric materials. Generally, for purpose of discussion, polarization of a piezoelectric material is defined as being in the “positive direction” from cation (e.g., Al atoms) to anion (e.g., N atoms) along the crystallographic axis points. Accordingly, as shown in FIG. 1A, when the first layer of the crystal lattice 100A is an Al layer and second layer in an upward direction (in the depicted orientation) is an N layer, the piezoelectric material including the crystal lattice 100A is said to have “positive polarity,” as indicated by the upward pointing arrow 150A. Conversely, as shown in FIG. 1B, when the first layer of the crystal lattice 100B is an N layer and second layer in an upward direction is an Al layer, the piezoelectric material including the crystal lattice 100B is said to have “negative polarity,” as indicated by the downward pointing arrow 150B. Notably, the orientation shown in FIG. 1B is the more standard convention in the field of polar nitride materials. A piezoelectric material having a single polarity (positive or negative) is limited in various characteristics, such as coupling coefficient kt², for example.

Generally, with regard to the coupling coefficient kt² of a BAW resonator, for example, it is assumed that the higher the value of the coupling coefficient kt², the better. Therefore, various techniques for increasing coupling coefficient kt² have been well investigated and developed, including doping of an aluminum nitride (AlN) piezoelectric layer with one or more rare earth elements, such as scandium (Sc), and/or adding temperature compensation layers to the acoustic stack.

However, certain applications require coupling coefficients kt² significantly lower than the intrinsic coupling coefficients kt² of typical piezoelectric materials, such as aluminum nitride (AlN). Such applications include, for example, sliver bands, such as band B13 (uplink: 777 MHz-787 MHz; downlink: 746 MHz-756 MHz) and band B30 (uplink: 2305 MHz-2315 MHz; downlink: 2350 MHz-2360 MHz), which require coupling coefficients kt² in the range of about 3 percent to about 4 percent (especially when over-temperature drift can be handled at the power amplifier level by backing off the power at the filter skirts). Conventionally, attempts to significantly lower coupling coefficients kt² are limited to adding temperature-compensating features, which necessarily introduce process complexity, higher cost and enhanced variability of resonator electrical parameters. Other applications include, for example, high frequency bands, such as bands in the vicinity of 3.5 GHz or 5 GHz, for example, which require regular coupling coefficients kt² values (e.g., approximately 6 percent or more). To accommodate higher frequencies, the piezoelectric layers of the BAW resonators become thinner (thickness scales inversely with frequency). Therefore, piezoelectric layers attempting to maintain regular coupling coefficients kt² for frequencies above 3 GHz, for example, become too thin to be reliable and consistently fabricated. Also, the resonator area becomes too small for equivalent electrical impedance. These factors lead to increased likelihood of power failures and enhanced nonlinearities. Use of acoustic stacks including piezoelectric materials with lower coupling coefficients kt² requires thicker piezoelectric layers, thereby mitigating these issues.

### BRIEF DESCRIPTION OF THE DRAWINGS

The illustrative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1A is a perspective view of an illustrative model of a crystal structure of aluminum nitride (AlN) in piezoelectric material having positive polarization.

FIG. 1B is a perspective view of an illustrative model of a crystal structure of AlN in piezoelectric material having negative polarization.

FIG. 2 is a simplified cross-sectional view of a BAW resonator device including a monolithic piezoelectric layer having opposite polarities, according to a representative embodiment.

FIG. 3 is a simplified cross-sectional view of a BAW resonator device including a split piezoelectric layer having opposite polarities, according to a representative embodiment.

FIG. 4 is a graph, and representative acoustic stacks of BAW resonator devices (e.g., with opposing polarities), showing coupling coefficient kt² as a function of proportional thicknesses of first and second portions of a monolithic piezoelectric layer, according to representative embodiments.

FIG. 5 is a flow diagram showing a method of forming a monolithic piezoelectric layer, as shown in FIG. 2, having opposite polarities in a continuous deposition sequence, according to a representative embodiment.

FIG. 6 is a cross-sectional view of a monolithic piezoelectric layer having opposite polarities, according to a representative embodiment.

FIG. 7 is a flow diagram showing a method of forming a split piezoelectric layer, as shown in FIG. 3, having opposite polarities, according to a representative embodiment.

FIG. 8A is a cross-sectional view of a BAW resonator device including a monolithic piezoelectric layer having opposite polarities, and performance enhancement features, according to a representative embodiment.

FIG. 8B is a cross-sectional view of a BAW resonator device including a split piezoelectric layer having opposite polarities and embedded metal interposer, and performance enhancement features, according to a representative embodiment.

FIG. 8C is a cross-sectional view of a BAW resonator device including a split piezoelectric layer having opposite polarities and non-embedded metal interposer, and performance enhancement features, according to a representative embodiment.

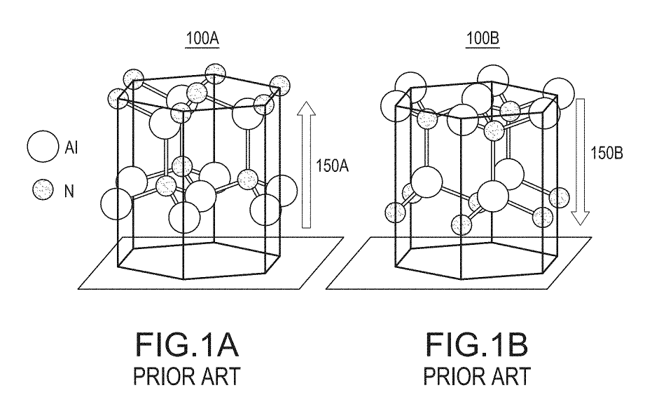

### DETAILED DESCRIPTION

It is to be understood that the terminology used herein is for purposes of describing particular embodiments only, and is not intended to be limiting. The defined terms are in addition to the technical and scientific meanings of the defined terms as commonly understood and accepted in the technical field of the present teachings.

As used in the specification and appended claims, the terms “a”, “an” and “the” include both singular and plural referents, unless the context clearly dictates otherwise. Thus, for example, “a device” includes one device and plural devices. As used in the specification and appended claims, and in addition to their ordinary meanings, the terms “substantial” or “substantially” mean to within acceptable limits or degree. For example, “substantially cancelled” means that one skilled in the art would consider the cancellation to be acceptable. As used in the specification and the appended claims and in addition to its ordinary meaning, the term “approximately” or “about” means to within an acceptable limit or amount to one of ordinary skill in the art. For example, “approximately the same” means that one of ordinary skill in the art would consider the items being compared to be the same.

In the following detailed description, for purposes of explanation and not limitation, specific details are set forth in order to provide a thorough understanding of illustrative embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the illustrative embodiments. Such methods and apparatuses are clearly within the scope of the present teachings.

Generally, it is understood that the drawings and the various elements depicted therein are not drawn to scale. Further, relative terms, such as “above,” “below,” “top,” “bottom,” “upper” and “lower” are used to describe the various elements' relationships to one another, as illustrated in the accompanying drawings. It is understood that these relative terms are intended to encompass different orientations of the device and/or elements in addition to the orientation depicted in the drawings. For example, if the device were inverted with respect to the view in the drawings, an element described as “above” another element, for example, would now be below that element.

Aspects of the present teachings are relevant to components of BAW resonator devices and filters, their materials and their methods of fabrication. Various details of such devices and corresponding methods of fabrication may be found, for example, in one or more of the following U.S. patent publications: U.S. Pat. No. 6,107,721 to Lakin; U.S. Pat. Nos. 5,587,620, 5,873,153, 6,507,983, 6,384,697, 7,275,292, 7,629,865 and 7,388,454 to Ruby et al.; U.S. Pat. No. 7,280,007 to Feng, et al.; U.S. Pat. No. 8,981,876 to Jamneala et al.; U.S. Patent App. Pub. Nos. 2010/0327697 and 2010/0327994 to Choy et al.; and U.S. Patent App. Pub. Nos. 2011/0180391 and 2012/0177816 to Larson, et al. The disclosures of these patents and patent applications are hereby specifically incorporated by reference in their entireties. It is emphasized that the components, materials and method of fabrication described in these patents and patent applications are representative and other methods of fabrication and materials within the purview of one of ordinary skill in the art are contemplated.

Generally, according to various embodiments, a piezoelectric layer of an acoustic stack in a resonator device has a composite polarity, meaning the piezoelectric layer includes both regular c-axis (negative polarity) and reverse c-axis (positive polarity) material. The composite polarity piezoelectric layer lowers the effective coupling coefficient kt² of the acoustic resonator device, without impacting the quality factor Q (Q-factor) or otherwise degrade performance of the acoustic resonator. The composite polarity piezoelectric layers are compatible with various BAW resonator devices, including FBARs and TC-FBARs, for example. Illustrative approaches include monolithic piezoelectric layers, which flip from negative polarity to positive polarity (by introducing oxygen into the gas atmosphere of the reaction chamber during fabrication at the position where the flip is desired), and split piezoelectric layers, which flip from positive polarity to negative polarity (by including a metal interposer at the position where the reversal in polarity is desired). Depending on the location within the piezoelectric layer where the reversal in polarity occurs, the coupling coefficient kt² of the acoustic resonator may be adjusted over an entire range of values from the intrinsic coupling coefficient kt² (no-degradation) to a coupling coefficient kt² equal to zero (full-degradation), depending on application specific design requirements of various implementations, without impacting the size of the acoustic resonator and/or features for improving the Q-factor (e.g., inner frames, outer frames, wings and/or air-bridges). Generally, the degradation of the coupling coefficient kt² relies on piezoelectric induced charge cancellation between the materials with opposite c-axes. In addition, the standard lateral performance enhancement features (lateral energy confinement features), such as frames, air-wings, air-bridges, may be incorporated to improve electrical and acoustic performance, regardless of the lower coupling coefficient kt².

According to a representative embodiment, a bulk acoustic wave (BAW) resonator device includes a bottom electrode disposed over a substrate and an acoustic reflector, a monolithic piezoelectric layer disposed over the bottom electrode, and a top electrode disposed over the second portion of the monolithic piezoelectric layer. The piezoelectric layer includes a first portion having a negative polarity and a second portion having a positive polarity that is substantially opposite to the negative polarity of the first portion with no discernible interface between the first and second portions. The first portion of the monolithic piezoelectric layer has a first thickness and the second portion of the monolithic piezoelectric layer has a second thickness that is not equal to the first thickness, thereby lowering a coupling coefficient kt² of the BAW resonator device while maintaining a combined thickness of the bottom electrode, the monolithic piezoelectric layer and the top electrode. The coupling coefficient kt² of the BAW resonator device varies proportionately with respect to a ratio of the first thickness to the second thickness.

According to another representative embodiment, a BAW resonator device includes a bottom electrode disposed over a substrate and an acoustic reflector, a seed layer formed of a dielectric material disposed over the bottom electrode, a split piezoelectric layer disposed on the seed layer, and a top electrode disposed over the second portion of the split piezoelectric layer. The split piezoelectric layer includes a first portion having a positive polarity due to the seed layer, a second portion having a negative polarity that is substantially opposite to the positive polarity of the first portion, and a metal interposer imbedded in the split piezoelectric layer between the first portion and the second portion. The first portion of the piezoelectric layer has a first thickness and the second portion of the piezoelectric layer has a second thickness that is not equal to the first thickness, thereby lowering a coupling coefficient kt² of the BAW resonator device. The coupling coefficient kt² of the BAW resonator device varies proportionately with respect to a ratio of the first thickness to the second thickness.

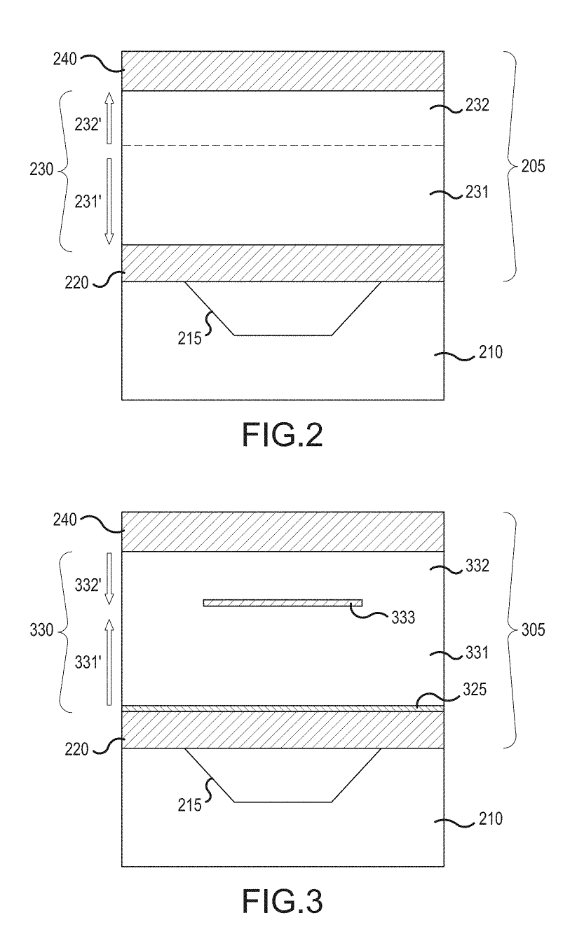

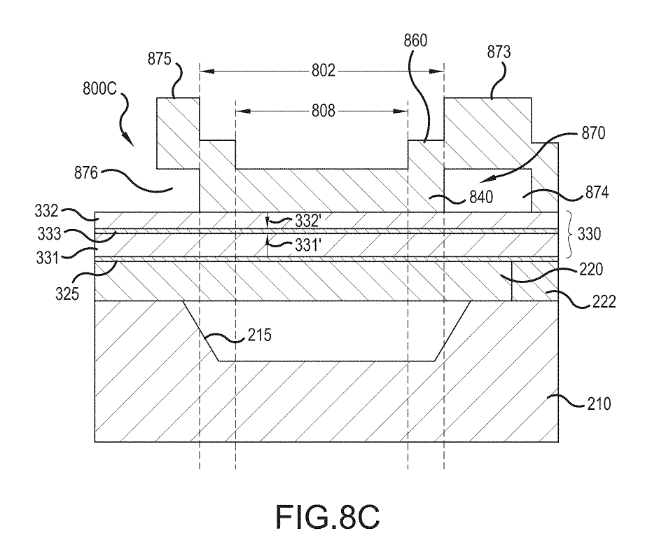

FIG. 2 is a simplified cross-sectional view of a BAW resonator device including a monolithic piezoelectric layer having opposite polarities, according to a representative embodiment. FIG. 2 represents a simplified BAW resonator device before the electrode patterning and release processes and is provided here for illustration purposes only. More detailed structure, which includes patterned electrodes and acoustic energy confinement features, for example, will be described in connection with FIG. 8A.

Referring to FIG. 2, BAW resonator device 200 is a thin film bulk acoustic resonator (FBAR). The BAW resonator device 200 includes a substrate 210 and a cavity 215 formed in a top surface of the substrate 210 as an acoustic reflector. A first (bottom) electrode 220 is disposed over the substrate 210 and the cavity 215, a monolithic piezoelectric layer 230 is disposed over the first electrode 220, and a second (top) electrode 240 is disposed over the monolithic piezoelectric layer 230, forming an acoustic stack 205. A passivation layer (not shown) may be formed over the top electrode 240. The passivation layer generally insulates the acoustic stack from the environment, including protection from moisture, corrosives, contaminants, debris and the like.

The substrate 210 may be formed of various materials compatible with semiconductor processes, such as silicon (Si), gallium arsenide (GaAs), indium phosphide (InP), or the like. Various illustrative fabrication techniques for forming an air cavity in a substrate are described by Grannen et al., U.S. Pat. No. 7,345,410 (issued Mar. 18, 2008), which is hereby incorporated by reference in its entirety. The first and second electrodes 220 and 240 are formed of electrically conductive material(s), such as molybdenum (Mo) or tungsten (W), and the passivation layer may be formed of a passivation material, such as silicon dioxide (SiO₂) or silicon nitride (Si₃N₄), for example, although other materials compatible for use with BAW resonator electrodes and passivation may be incorporated, without departing from the scope of the present teachings. Also, in the depicted embodiment, the monolithic piezoelectric layer 230 is formed of aluminum nitride (AlN), for example. Other piezoelectric materials in which c-axis reversal may be induced, such as zinc oxide (ZnO), for example, may be incorporated without departing from the scope of the present teachings.

The monolithic piezoelectric layer 230 includes a first portion 231 and a second portion 232, with no discernible interface between the first and second portions 231 and 232. The first portion 231 has a negative polarity (or “regular c-axis”) directed substantially toward the first electrode 220 (indicated by downward pointing arrow 231′), and the second portion 232 has a positive polarity (or “reversed c-axis”) directed substantially away from the first electrode 220 (indicated by upward pointing arrow 232′). That is, the first and second portions 231 and 232 of the monolithic piezoelectric layer 230 have substantially opposite polarities. The vicinity at which the negative polarity flips to the positive polarity is indicated by dashed line 233, for the sake of convenience. The respective thicknesses (in the vertical direction shown in the orientation of FIG. 2) of the first portion 231 and the second portion 232 differ relative to one another. The extent of this relative difference in thicknesses determines the coupling coefficient kt² of the BAW resonator device 200.

More particularly, the respective thicknesses of the first and second portions 231 and 232 of the monolithic piezoelectric layer 230 determine the coupling coefficients kt² at resonance frequencies of both the first and the second harmonics of the BAW resonator device 200. Moreover, the coupling coefficients kt² at the first and the second harmonic resonances of the BAW resonator device 200 vary inversely proportionately to one another. So, for example, as the coupling coefficient kt² at the first harmonic resonance decreases, the coupling coefficient kt² at the second harmonic resonance increases, and vice versa. For purposes of this disclosure, only the first harmonic resonance is addressed, so references herein to the coupling coefficient kt² of the BAW resonator device 200 (as well as other BAW resonator devices discussed below) are understood to refer to the coupling coefficient kt² of the first harmonic resonance, unless otherwise specified.

In the depicted embodiment, the first portion 231 is thicker than the second portion 232, although in alternative embodiments, the second portion 232 may be thicker than the first portion 231, without departing from the scope of the present teachings. As discussed further below, the coupling coefficient kt² of the BAW resonator device 200 is about zero when the respective thicknesses of the first and second portions 231 and 232 are substantially equal. However, when the respective thicknesses of the first and second portions 231 and 232 are different from one another, the coupling coefficient kt² of the BAW resonator device becomes greater than zero (but still less than what the coupling coefficient kt² would be if the piezoelectric layer were comprised entirely of material with only a negative polarity or a positive polarity). Therefore, the coupling coefficient kt² of the BAW resonator device 200 may be adjusted to a value lower than the coupling coefficient kt² of the piezoelectric material (e.g., AlN), but greater than zero, by forming the monolithic piezoelectric layer 230 with the first and second portions 231 and 232 having different relative thicknesses.

Thus, the first portion 231 of the monolithic piezoelectric layer 230 has a first thickness and the second portion 232 of the monolithic piezoelectric layer has a second thickness that is not equal to the first thickness, thereby lowering a coupling coefficient kt² of the BAW resonator device 200, while maintaining a combined thickness of the first electrode 220, the monolithic piezoelectric layer 230 and the top electrode 240. The coupling coefficient kt² of the BAW resonator device 200 varies proportionately with respect to a ratio of the first thickness to the second thickness.

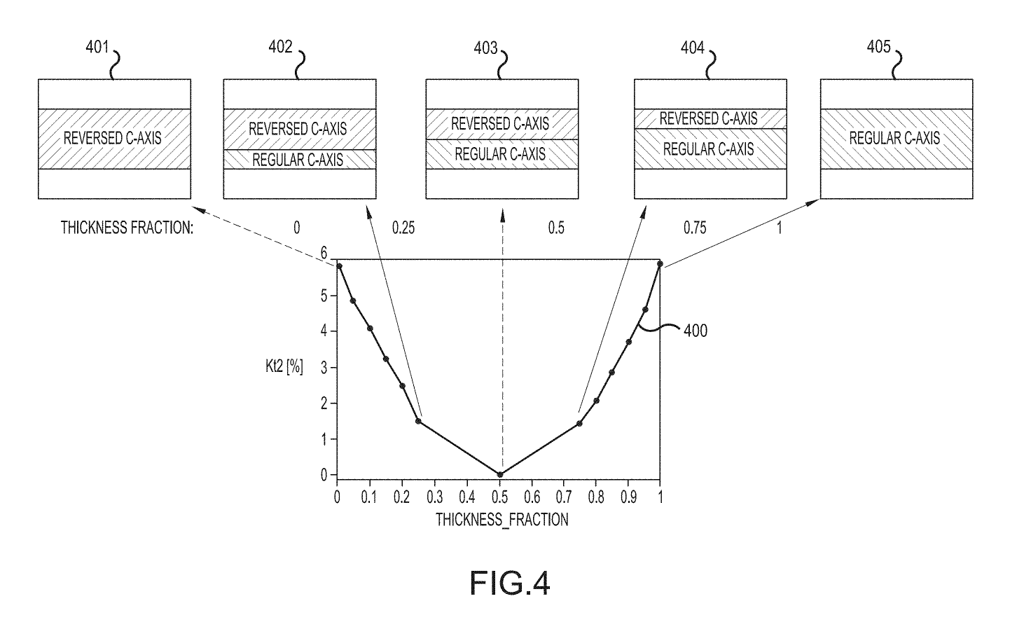

FIG. 3 is a simplified cross-sectional view of a BAW resonator device including a split piezoelectric layer having opposite polarities, according to a representative embodiment. FIG. 3 represents a simplified BAW resonator device before the electrode patterning and release processes, and is provided here for illustration purposes only. More detailed structure, which includes patterned electrodes and acoustic energy confinement features, for example, will be described in connection with FIG. 8B.

Referring to FIG. 3, BAW resonator device 300 is likewise an FBAR. The BAW resonator device 300 includes substrate 210 and cavity 215 formed in a top surface of the substrate 210 as an acoustic reflector. First (bottom) electrode 220 is disposed over the substrate 210 and the cavity 215, a seed layer comprising aluminum oxynitride (AlON, or oxide) 325 is disposed over the first electrode 220, a split piezoelectric layer 330 is disposed over the oxide seed layer 325, and second (top) electrode 240 is disposed over the split piezoelectric layer 330, forming an acoustic stack 305. A passivation layer (not shown) may be formed over the top electrode 240. The passivation layer generally insulates the acoustic stack from the environment, including protection from moisture, corrosives, contaminants, debris and the like.

Like the monolithic piezoelectric layer 230 in FIG. 2, the split piezoelectric layer 330 is formed of aluminum nitride (AlN), for example. Other piezoelectric materials in which c-axis reversal may be induced, such as zinc oxide (ZnO), for example, may be incorporated without departing from the scope of the present teachings. The split piezoelectric layer 330 includes a first portion 331, a second portion 332 and an embedded metal interposer 333 formed between the first and the second portions 331 and 332, thereby separating portions of the first and the second portions 331 and 332 from one another. In particular, the metal interposer 333 extends across the entire active region of the split piezoelectric layer 330, but not across the entire piezoelectric layer 330, as will be described in detail with reference to FIG. 8B. More particularly, the first portion 331 is formed on the seed layer 325, the metal interposer 333 is formed on the first portion 331, and the second portion 332 is formed on the metal interposer 333. Because the first portion 331 is formed on the seed layer 325, as opposed to the surface of the first electrode 220, the seed layer 325 causes the first portion 331 to have a positive polarity (or “reversed c-axis”) directed substantially away from the first electrode 220 (indicated by upward pointing arrow 331′). The metal interposer 333 causes the second portion 332 to have a negative polarity (or “regular c-axis”) directed substantially toward the first electrode 220 (indicated by downward pointing arrow 332′). That is, the first and second portions 331 and 332 of the split piezoelectric layer 330 have substantially opposite polarities. The respective thicknesses (in the vertical direction shown in the orientation of FIG. 3) of the first portion 331 and the second portion 332 differ relative to one another. The extent of this relative difference in thicknesses determines the coupling coefficient kt² of the BAW resonator device 300, as discussed above with reference to BAW resonator device 200 in FIG. 2.

As in FIG. 2, in the embodiment depicted in FIG. 3, the first portion 331 is thicker than the second portion 332, although in alternative embodiments, the second portion 332 may be thicker than the first portion 331, without departing from the scope of the present teachings. The thickness of each of the first and second portions 331 and 332 is determined by the placement of the metal interposer 333, which creates an interface between the first and second portions 331 and 332. As discussed further below, the coupling coefficient kt² of the BAW resonator device 300 is about zero when the respective thicknesses of the first and second portions 331 and 332 are substantially equal. However, when the respective thicknesses of the first and second portions 331 and 332 are different from one another, the coupling coefficient kt² of the BAW resonator device becomes greater than zero (but still less than what the coupling coefficient kt² would be if the piezoelectric layer were comprised entirely of material with only a negative polarity or a positive polarity). Therefore, the coupling coefficient kt² of the BAW resonator device 300 may be adjusted to a value lower than the coupling coefficient kt² of the piezoelectric material (e.g., AlN), but greater than zero, by forming the split piezoelectric layer 330 with the first and second portions 331 and 332 having different relative thicknesses.

Thus, the first portion 331 of the split piezoelectric layer 330 has a first thickness and the second portion 332 of the split piezoelectric layer has a second thickness that is not equal to the first thickness, thereby lowering a coupling coefficient kt² of the BAW resonator device 300, while maintaining a combined thickness of the seed layer 325, the first electrode 220, the split piezoelectric layer 330 and the top electrode 240. The coupling coefficient kt² of the BAW resonator device 300 varies proportionately with respect to a ratio of the first thickness to the second thickness.

In alternative embodiments of the BAW resonator devices 200 and 300, an acoustic mirror, such as a distributed Bragg reflector (DBR) (not shown), may be formed as the acoustic reflector in place of the cavity 215, without departing from the scope of the present teachings. The DBR may be formed on the top surface of the substrate 210, and may include one or more acoustic reflector layer pairs sequentially stacked on the substrate 210. Each of the stacked acoustic reflector layer pairs includes two layers, i.e., a first layer with a first acoustic impedance and a second layer with a second acoustic impedance stacked on the first layer. Within each acoustic reflector layer pair of the DBR, the first acoustic impedance is less than the second acoustic impedance. Thus, for example, the first layer may be formed of various low acoustic impedance materials, such as boron silicate glass (BSG), tetra-ethyl-ortho-silicate (TEOS), silicon oxide (SiOₓ) or silicon nitride (SiNₓ) (where x is an integer), carbon-doped silicon oxide (CDO), titanium (Ti) or aluminum, and each of the second conductive layers may be formed of various high acoustic impedance materials, such as tungsten (W), molybdenum (Mo), niobium molybdenum (NbMo), iridium (Ir), hafnium oxide (HfO₂), aluminum oxide (Al₂O₃), diamond or diamond-like carbon (DLC). Various illustrative fabrication techniques of acoustic mirrors are described by Larson III, et al., U.S. Pat. No. 7,358,831 (issued Apr. 15, 2008), which is hereby incorporated by reference in its entirety.

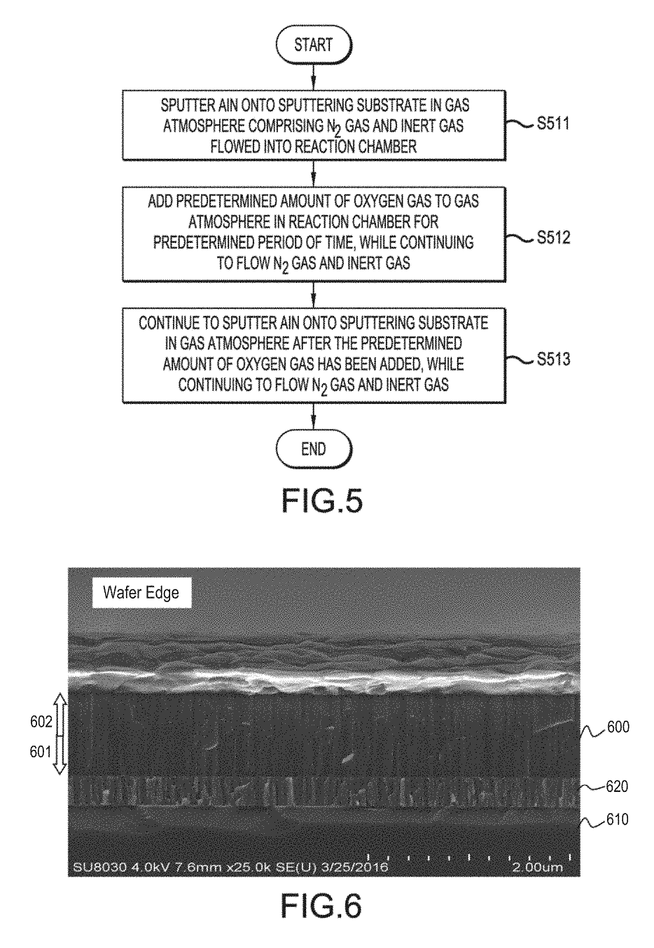

FIG. 4 is a graph, and representative acoustic stacks of BAW resonator devices (e.g., with opposing polarities), showing measured coupling coefficient kt² as a function of proportional thicknesses of first and second portions of a monolithic piezoelectric layer, according to representative embodiments.

Referring to FIG. 4, the monolithic piezoelectric layer may have first and second portions having opposing polarities, as shown in FIG. 2, although the graph includes the two extremes of the monolithic piezoelectric layer having only one polarity of the two polarities for comparative purposes. For purposes of illustration, the monolithic piezoelectric layer is formed of aluminum nitride (AlN), and has a range of coupling coefficient kt² values (y-axis) from 0 percent to about 6 percent. The thicknesses of the first and second portions are indicated as percentages of a total thickness of the monolithic piezoelectric layer (x-axis), thus having a range from zero (0) to one (1.0), where 1.0 indicates 100 percent. The curve 400 illustrates the portion of the monolithic piezoelectric layer having negative polarity (regular c-axis), which corresponds to the first portion (e.g., first portion 231). Of course, a similar curve may be determined based on the portion of the monolithic piezoelectric layer having positive polarity (reversed c-axis), which corresponds to the second portion (e.g., second portion 232), as would be apparent to one skilled in the art. Likewise, a similar graph may be determined based on relative portions of acoustic stacks having a split piezoelectric layer (e.g., with first and second portions having opposing polarities, as shown in FIG. 3), as would be apparent to one skilled in the art.

Representative acoustic stacks 401 to 405 of BAW resonators are shown corresponding to the various proportions of the acoustic stacks 401 to 405 includes a first (bottom) electrode, a monolithic piezoelectric layer, and a second (top) electrode, as discussed above with reference to FIG. 2.

As shown in FIG. 4, when there is no first portion of the monolithic piezoelectric layer (i.e., no regular c-axis), the monolithic piezoelectric layer is formed of only reversed c-axis material, as shown by acoustic stack 401. The corresponding coupling coefficient kt² is at the maximum, which is about 6 percent in the depicted example. When the first portion of the monolithic piezoelectric layer is 25 percent of the monolithic piezoelectric layer (and thus the second portion of the monolithic piezoelectric layer is 75 percent), as shown by acoustic stack 402, the corresponding coupling coefficient kt² is about 1.5 percent. When the first portion of the monolithic piezoelectric layer is 50 percent of the monolithic piezoelectric layer (and thus the second portion of the monolithic piezoelectric layer is also 50 percent), as shown by acoustic stack 403, the corresponding coupling coefficient kt² is about 0. When the first portion of the monolithic piezoelectric layer is 75 percent of the monolithic piezoelectric layer (and thus the second portion of the monolithic piezoelectric layer is 25 percent), as shown by acoustic stack 404, which is similar in relative proportions to the acoustic stack 205 in FIG. 2, the corresponding coupling coefficient kt² is again about 1.5 percent. Lastly, when there is no second portion of the monolithic piezoelectric layer (i.e., no reversed c-axis), the monolithic piezoelectric layer is formed of only regular c-axis material, as shown by acoustic stack 405. The corresponding coupling coefficient kt² is again at the maximum, which is about 6 percent in the depicted example.

FIG. 4 includes additional points for on the curve 400, which likewise indicate that as the relative proportions of the regular and reversed c-axis piezoelectric materials become more equal to one another, the coupling coefficients kt² become smaller, although corresponding acoustic stacks are not shown for every combination, or the sake of convenience. For example, referring again to curve 400, when the first portion of the monolithic piezoelectric layer is 90 percent of the monolithic piezoelectric layer (and thus the second portion of the monolithic piezoelectric layer is 10 percent), the corresponding coupling coefficient kt² is about 4.4 percent, and when the first portion of the monolithic piezoelectric layer drops to 80 percent of the monolithic piezoelectric layer (and thus the second portion of the monolithic piezoelectric layer is 20 percent), the corresponding coupling coefficient kt² is about 2.0 percent. That is, according to the graph shown in FIG. 4, generally, the coupling coefficient kt² of the BAW resonator device varies proportionately with respect to a ratio of a thickness of the first portion of monolithic piezoelectric layer having (negative polarity/regular c-axis) to a thickness of the second portion of monolithic piezoelectric layer having (positive polarity/reverse c-axis). Accordingly, by adjusting the proportions of regular c-axis (negative polarity) and the reverse c-axis (positive polarity) piezoelectric material in the design stage, various different coupling coefficients kt² may be obtained to provide unique benefits for any particular situation or to meet application specific design requirements of various implementations.

Further, regardless of the respective proportions, the thicknesses of each of the first electrode, the second electrode and the monolithic piezoelectric layer remains the same, and thus the combined thickness of the first electrode, the piezoelectric layer and the second electrode (e.g., the thickness of the acoustic stacks 401-405) remain the same. Also, even at the lower the coupling coefficients kt², the Q-factor of the BAW resonator device including the acoustic stack remains about the same as the Q-factor of a BAW resonator including a piezoelectric layer having polarity entirely in one direction (e.g., positive or negative polarity).

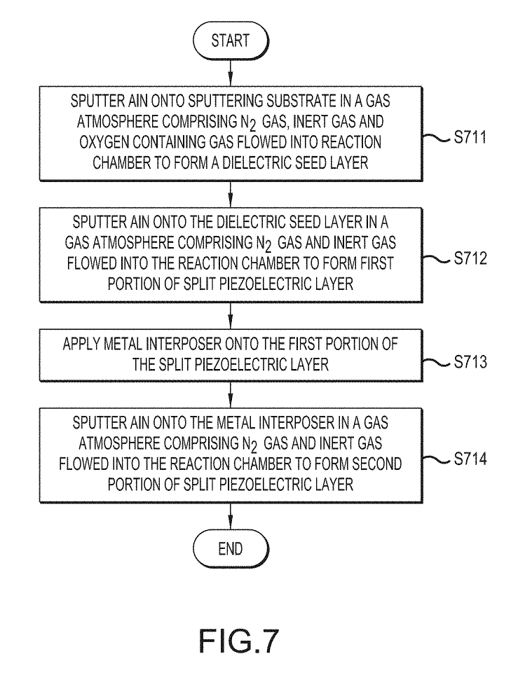

FIG. 5 is a flow diagram showing a method of forming a monolithic piezoelectric layer, as shown in FIG. 2, having opposite polarities in a continuous deposition sequence, according to a representative embodiment.

Referring to FIG. 5, in block S511, aluminum nitride (AlN) is reactively sputtered onto a sputtering substrate inside a reaction chamber during a first phase of the deposition sequence. The reaction chamber may be part of a planar magnetron system, for example. The reaction chamber has a gas atmosphere that initially includes nitrogen (N₂) gas and an inert gas, such as argon (Ar), for example, which continuously flow into reaction chamber in approximately a 3:1 ratio of nitrogen to argon throughout the deposition sequence. This first phase causes growth on the sputtering substrate of a piezoelectric layer having a polarity in a negative direction. In various embodiments, the sputtering substrate may be formed of metal, such as molybdenum (Mo) and/or tungsten (W), typically used for BAW resonator electrodes, for example, although other sputtering substrates may be used, such as other metals, silicon (Si) and/or silicon carbide (SiC), without departing from the scope of the present teachings.

In block S512, a predetermined amount of oxygen containing gas is added to the gas atmosphere over a short predetermined period of time during a second phase of the deposition sequence. The oxygen containing gas may be diatomic or triatomic oxygen containing gas, such as oxygen (O₂) or ozone (O₃), for example, although other suitable oxygen containing gases may be used without departing from the scope of the present teachings. Notably, the sputtering of the AlN continues, without interruption and without alteration of the proportionate amounts of the nitrogen gas (N₂) and the inert gas, while the predetermined amount of oxygen containing gas flows into the gas atmosphere over the predetermined period of time. That is, in an embodiment, N₂ and Ar gas continue to flow into the reaction chamber in approximately a 3:1 ratio of N₂ to Ar, as oxygen (e.g., O₂ or O₃) gas also flows into the reaction chamber. In various embodiments, the predetermined amount of oxygen containing gas added to the gas atmosphere may be in a range from about 50 micromoles to about 5 millimoles, and the predetermined period of time during which the predetermined amount of oxygen containing gas is added to the gas atmosphere may be in a range from about one (1) second to about sixty (60) seconds, for example. In other words, the plasma (e.g., N₂ and Ar) is never turned off, and the wafer (substrate) on which the monolithic piezoelectric layer is being formed is never removed from the sputtering chamber, resulting in the monolithic character of the piezoelectric layer, which provides better material quality and like improved device performance. For example, based on mass-flows, the oxygen composition of the gas atmosphere may be about 2 percent when the oxygen is briefly injected. This results in an aluminum oxynitride (ALON) portion of the final monolithic piezoelectric layer, integrated in the AlN material, having a thickness in a range of about 5 nm to about 20 bm, which is relatively oxygen rich and very thin (which is beneficial for performance).

In block S513, after the predetermined period of time for adding the predetermined amount of oxygen gas ends, the AlN still continues to be reactively sputtered onto the sputtering substrate inside the reaction chamber during a third phase of the sputtering deposition. That is, in an embodiment, N₂ and Ar gas continue to flow into the reaction chamber, without interruption, in approximately a 3:1 ratio of N₂ to Ar for the remainder of the deposition sequence. Accordingly, due to the continuous nature of the deposition sequence, even while the oxygen containing gas is added and the polarity of the piezoelectric layer flips, the resulting piezoelectric layer is monolithic. That is, there is no discernible interface between the portion of the piezoelectric layer having the negative polarity and the portion of the piezoelectric layer having the positive (opposite) polarity. The term “discernible interface” in the context of this disclosure refers to an interface in the piezoelectric material visibly observable by physical analysis tools, such as scanning electron microscopy. Thus, it follows that the term “no discernible interface” means that there is no visible interface between the regions of opposite polarity in the piezoelectric layer that is observable at less than about 25000 times magnification (e.g., using a scanning electron microscope). Stated differently, due to the continuous nature of the deposition sequence, even as the oxygen containing gas is added and the polarity of the piezoelectric layer flips, the resulting piezoelectric layer is monolithic, in that there is no “distinct layer” of material separating the first portion of the piezoelectric layer having the negative polarity and the second portion of the piezoelectric layer having the positive polarity. Rather, the AlN material provides an uninterrupted, single piezoelectric layer. Although oxygen molecules are present in the vicinity of the finished piezoelectric layer where the polarity flips, these oxygen molecules are generally diffused, and not sufficiently organized into a material layer (e.g., aluminum oxynitride (AlON)) distinct from or otherwise separating the surrounding AlN piezoelectric material.

Accordingly, the addition of the predetermined amount of oxygen containing gas causes the polarity of the piezoelectric layer to invert from a negative direction to a positive direction, opposite the negative direction. In other words, when the piezoelectric layer is formed having a negative polarity (directed substantially toward the sputtering substrate) during the first phase of the deposition sequence, it flips to a positive polarity (directed substantially away from the sputtering substrate) at the second phase, and continues in this flipped polarity during the third phase of the deposition sequence. Further, the addition of the predetermined amount of oxygen containing gas over the predetermined period of time, during which the predetermined amount of oxygen containing gas is flowed into the reaction chamber, is timed to cause the polarity of the piezoelectric layer to invert at a predetermined time during the deposition sequence to provide the desired coupling coefficient kt² based on the relative thicknesses of the first and second portions of the monolithic piezoelectric layer. This ultimately results in the first portion of the piezoelectric layer with a negative polarity having a different thickness than the second portion of the piezoelectric layer with a positive polarity. The amount of oxygen containing gas and the period of time over which the amount of oxygen containing gas is flowed into the reaction chamber needed to flip the polarity of the piezoelectric layer is determined empirically.

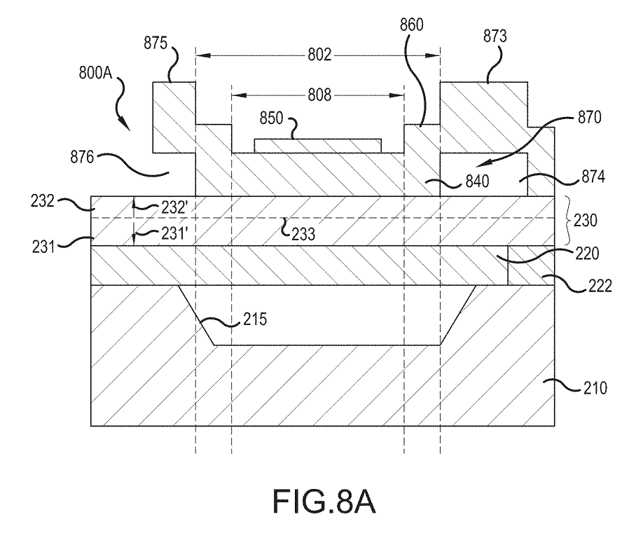

FIG. 6 is a cross-sectional view of a monolithic piezoelectric layer having opposite polarities, according to a representative embodiment. Referring to FIG. 6, monolithic piezoelectric layer 600 has been formed according to the method described above with reference to FIG. 5. The monolithic piezoelectric layer 600 includes no discernible interface between a first portion having negative polarity (indicated by arrow 601) and a second portion having positive polarity (indicated by arrow 602). In the example shown in FIG. 6, the first and second portions have approximately the same thicknesses, which would result in a coupling coefficient kt² approximately equal to zero, as shown in FIG. 4, for example. However, as described above, according to various embodiments, the first and second portions do not have the same thicknesses, and thus the area at which the polarity of the monolithic piezoelectric layer as shown in FIG. 6 flips from negative to positive would be before or after the halfway point, although the monolithic piezoelectric layer 600 would still include no discernible interface.

The illustrative monolithic piezoelectric layer 600, fabricated according to the method of FIG. 5, for example, may be implemented as the piezoelectric layer as part of an acoustic stack of a BAW resonator. That is, the acoustic stack may include a bottom electrode 620 formed over resonator substrate 610 and an acoustic reflector, the monolithic piezoelectric layer 600 formed on the bottom electrode 620, and a top electrode ultimately formed on the monolithic piezoelectric layer 600. A passivation layer optionally may be formed on the top electrode, as well. The substrate, bottom electrode, piezoelectric layer, and top electrode may be substantially the same as described above with reference to FIG. 2.

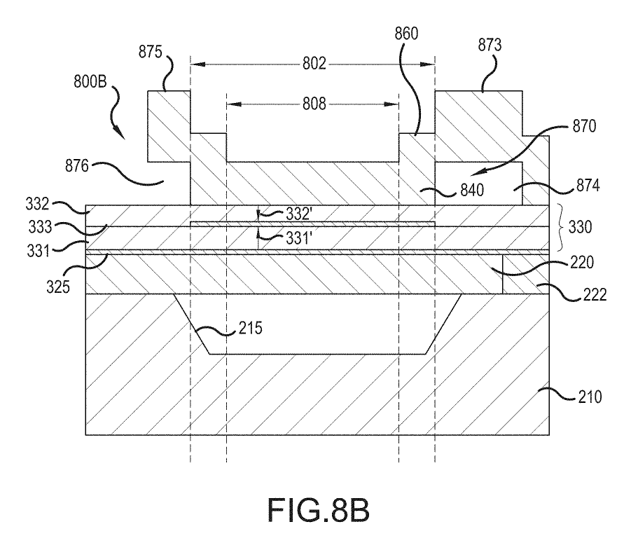

FIG. 7 is a flow diagram showing a method of forming a split piezoelectric layer, as shown in FIG. 3, having opposite polarities, according to a representative embodiment.

Referring to FIG. 7, a seed layer is applied to a sputtering substrate in block S711 by sputtering, for example. The sputtering substrate may be a first electrode layer formed of a metal, such as molybdenum (Mo) and/or tungsten (W), for example, which had been previously deposited over a substrate (or wafer) formed of silicon (Si), gallium arsenide (GaAs) or indium phosphide (InP), for example. The seed layer is a material that causes polarity in subsequently applied piezoelectric material to reverse polarity, such as flipping from a negative polarity (regular c-axis) to a positive polarity (reversed c-axis), as discussed above. For example, when the piezoelectric material includes aluminum nitride (AlN), the seed layer may be aluminum oxynitride (AlON). In this case, aluminum nitride (AlN) is reactively sputtered onto the sputtering substrate inside a reaction chamber during a first phase of the deposition sequence. The reaction chamber may be part of a planar magnetron system, for example. The reaction chamber has a gas atmosphere that includes nitrogen (N₂) gas and an inert gas, such as argon (Ar), for example, which flow into the reaction chamber in approximately a 3:1 ratio of nitrogen to argon throughout the first phase, along with a diatomic or triatomic oxygen containing gas, such as oxygen (O₂) or ozone (O₃), for example. The gas atmosphere reacts with the aluminum nitride (AlN), causing growth of ALON (the seed layer) on the sputtering substrate. The seed layer is grown to a thickness of about 10 nm to about 100 nm, although various thicknesses may be used to provide unique benefits for any particular situation or to meet application specific design requirements of various implementations.

In block S712, piezoelectric material is applied to the seed layer to form a first portion of the split piezoelectric layer. For example, in block S712, aluminum nitride (AlN) is reactively sputtered onto the ALON seed layer inside the reaction chamber during a second phase of the deposition sequence. The oxygen containing gas has been removed, so that the reaction chamber has a gas atmosphere that includes nitrogen (N₂) gas and the inert gas, such as argon (Ar), for example, which flow into the reaction chamber in approximately a 3:1 ratio of nitrogen to argon throughout the second phase. This second phase causes growth on the ALON seed layer of the piezoelectric material having a polarity in a positive direction (reversed c-axis).

In block S713, the stack including the first portion of the split piezoelectric layer sputtered onto the seed layer is removed from the reaction chamber, and a metal interposer is formed and patterned on the first portion of the split piezoelectric layer. The metal interposer may be formed by sputtering, chemical vapor deposition (CVD) or atomic layer deposition (ALD), for example, using molybdenum (Mo), tungsten (W), or other compatible metal or combinations of metal. Of course, other application techniques may be incorporated without departing from the scope of the present teachings. The metal interposer is formed to be relatively thin in order to minimize impact on the piezoelectric characteristics of the final split piezoelectric layer. For example, the metal interposer may be formed between about 10 nm and about 100 nm. Also, the metal interposer is patterned in order to avoid parasitic transducer effect resulting from electrical excitation of the first portion of the split piezoelectric layer in the region outside of the main membrane region (as defined in relation to FIGS. 8A and 8B below), that is in the region where the metal interposer, the first portion of the split piezoelectric layer, the bottom electrode and the substrate overlap.

The stack is then returned to the reaction chamber, where additional piezoelectric material is applied to the seed layer in block S714 in a third phase of the deposition sequence. The reaction chamber has a gas atmosphere that includes nitrogen (N₂) gas and an inert gas, such as argon (Ar), for example, which flow into the reaction chamber in approximately a 3:1 ratio of nitrogen to argon throughout the third phase. This third phase causes growth on the metal interposer of piezoelectric material having a polarity in a negative direction (regular c-axis), resulting in the split piezoelectric layer. That is, the split piezoelectric layer in the present example includes a first portion having a positive polarity (reversed c-axis), a metal interposer, and a second portion have a negative polarity (regular c-axis). The addition of the predetermined amount of oxygen containing gas causes the polarity of the first portion of the piezoelectric layer to invert from a negative direction to a positive direction, opposite the negative direction. Then, application of the metal interposer causes the polarity of the second portion of the piezoelectric layer to invert from the positive direction to the negative direction. In other words, the split piezoelectric layer is formed having a positive polarity during the second phase of the deposition sequence, and flips to having the negative polarity during the third phase of the deposition sequence due to the presence of the metal interposer. Further, the addition of the metal interposer is timed to cause the polarity of the split piezoelectric layer to invert to the negative polarity at a predetermined time during the deposition sequence to provide the desired coupling coefficient kt² based on the relative thicknesses of the first and second portions of the split piezoelectric layer.

As mentioned above, various performance enhancement features may be included in the BAW resonator devices having piezoelectric layers with opposing polarities. Such performance enhancement features include inner frames, outer frames, air-wings and/or air-bridges, combinations of which may increase the Q-factor of the BAW resonator device, while maintaining the desired low coupling coefficient kt².

Generally, an acoustic resonator comprises an acoustic stack formed by a piezoelectric layer disposed between first (bottom) and second (top) electrodes, disposed on a substrate over an air cavity, a DBR or other acoustic reflector, as discussed above. An overlap between the first electrode, the piezoelectric layer and the second electrode over the acoustic reflector cavity defines a main membrane region. Outer frames may be formed on the second electrode, defining an active region within the main membrane region. In addition, an inner frame may be formed by depositing additional material in a center region of the second electrode (main part of the acoustic resonator), and/or an air-ring may be formed outside an outer boundary of the main membrane region. The air-ring may be formed between the piezoelectric layer and the second electrode, such that it comprises an air-bridge on the connection side of the top electrode and an air-wing along the remaining outside perimeter.

A frame may be formed by adding a layer of material, usually an electrically conducting material (although dielectric material is possible as well), to the second electrode and/or the second electrode. The frame can be either a composite frame or an add-on frame. In the embodiments depicted herein, the frames are shown as add-on frames, for the sake of convenience, although composite frames may be included instead without departing from the scope of the present teachings. Examples of construction of various composite and add-on frames are provided by U.S. Patent App. Pub. No. 2014/0118087 to Burak et al., which is hereby incorporated by reference in its entirety.

A frame generally suppresses electrically excited piston mode in the frame region, and it reflects and otherwise resonantly suppresses propagating eigenmodes in lateral directions, with both effects simultaneously improving operation of the acoustic resonator. This is because the frame's presence generally produces at least one of a cutoff frequency mismatch and an acoustic impedance mismatch between the frame region and other portions of the active region. A frame that lowers the cutoff frequency in the frame region as compared to the active region may be referred to as a Low Velocity Frame (LVF), while a frame that increases the cutoff frequency in the frame region as compared to the main active region may be referred to as a High Velocity Frame (HVF).

A frame with lower effective sound velocity than the corresponding effective sound velocity of the active region (i.e., an LVF) generally increases parallel resistance Rp and Q-factor of the acoustic resonator above the cutoff frequency of the active region. Conversely, a frame with a higher effective sound velocity than the corresponding effective sound velocity of the active region (i.e., an HVF) generally decreases series resistance Rs and increases Q-factor of the acoustic resonator below the cutoff frequency of the main active region. A typical low velocity frame, for example, effectively provides a region with significantly lower cutoff frequency than the active region and therefore minimizes the amplitude of the electrically excited piston mode towards the edge of the top electrode in the frame region. Furthermore, it provides two interfaces (impedance miss-match planes), which increase reflection of propagating eigenmodes. These propagating eigenmodes are mechanically excited at active/frame interface, and both mechanically and electrically excited at the top electrode edge. Where the width of the frame is properly designed for a given eigenmode, it results in resonantly enhanced suppression of that particular eigenmode. In addition, a sufficiently wide low velocity frame provides a region for smooth decay of the evanescent and complex modes, which are excited by similar mechanisms as the propagating eigenmodes. The combination of the above effects yields better energy confinement and higher Q-factor at a parallel resonance frequency Fp.

Various additional examples of frames, as well as related materials and operating characteristics, are described in the above cited U.S. Pat. Nos. 9,401,692 and 9,425,764 to Burak et al., which are hereby incorporated by reference in their entireties. As explained in those applications, frames can be placed in various alternative locations and configurations relative to other portions of an acoustic resonator, such as the electrodes and piezoelectric layer of an acoustic stack. Additionally, their dimensions, materials, relative positioning, and so on, can be adjusted to achieve specific design objectives, such as a target resonance frequency, series resistance Rs, parallel resistance Rp, or electromechanical coupling coefficient kt². Although the following description presents several embodiments in the form of FBAR and SMR devices, several of the described concepts could be implemented in other forms of acoustic resonators.

FIG. 8A is a cross-sectional view of a BAW resonator device including a monolithic piezoelectric layer having opposite polarities, and performance enhancement features, according to a representative embodiment. FIG. 8B is a cross-sectional view of a BAW resonator device including a split piezoelectric layer having opposite polarities, and performance enhancement features, according to a representative embodiment. In various embodiments, FIGS. 8A and 8B may be cross-sections of BAW resonator devices having apodized, polygonal shapes from a top plan view.

Referring to FIG. 8A, the BAW resonator device 800A includes substrate 210 defining an air cavity 215, first (bottom) electrode 220 disposed on the substrate 210 and air cavity 215, a planarization layer 222 disposed adjacent to first electrode 220 on the substrate 210, monolithic piezoelectric layer 230 disposed on the first electrode 220 and the planarization layer 222, and a second (top) electrode 840 disposed on the monolithic piezoelectric layer 230. Collectively, the first electrode 220, the monolithic piezoelectric layer 230, and the second electrode 840 constitute an acoustic stack of the BAW resonator device 800A. Also, an overlap among the first electrode 220, the monolithic piezoelectric layer 230 and the second electrode 840 over the air cavity 215 defines a main membrane region 802 of the BAW resonator device 800A. Here, an overlap means the region where the first electrode 220, the monolithic piezoelectric layer 230 and the second electrode 840 are mechanically attached to each other in vertical direction. In the depicted example, the outer edges of the second electrode 840 correspond to the inner edges of air-gap 874 and air-gap 876, defined by the air-bridge 873 and the air-wing 875, respectively (as discussed below), even though the air-bridge 873 and the air-wing 875 may be integral with the second electrode 840. Dotted vertical lines indicate the boundary of the main membrane region 802.

As discussed above, the monolithic piezoelectric layer 230 includes a first portion 231 and a second portion 232, with no discernible interface between the first and second portions 231 and 232. The first portion 231 has a negative polarity directed substantially toward the first electrode 220 (indicated by downward pointing arrow 231′), and the second portion 232 has a positive polarity directed substantially away from the first electrode 220 (indicated by upward pointing arrow 232′). The vicinity at which the negative polarity flips to the positive polarity is indicated by dashed line 233, for the sake of convenience. The respective thicknesses (in the vertical direction shown in the orientation of FIG. 8A) of the first portion 231 and the second portion 232 differ relative to one another. The extent of this relative difference in thicknesses determines the coupling coefficient kt² of the BAW resonator device 800A, as discussed above.

In addition, the BAW resonator device 800A includes multiple lateral performance enhancement features, which increase the Q-factor, for example, associated with the second electrode 840. The performance enhancement features includes inner frame 850 formed in a center region on the second electrode 840, outer frame 860 formed (positioned) in an outer region on the second electrode 840 (e.g., around an outer perimeter region of the second electrode 840), and air-ring 870 formed around an outer perimeter of the outer frame 860. The air ring 870 may be formed outside an outer boundary of the main membrane region 802, extending along at least a portion of the outer perimeter of the BAW resonator device. The air-ring 870 is be formed between the monolithic piezoelectric layer 230 and the second electrode 840, such that it comprises an air-bridge 873 on a connection side of the second electrode 840 and an air-wing 875 along the remaining outside perimeter. The air-bridge 873 creates an enclosed air-gap 874 beneath the air-bridge 873 and the monolithic piezoelectric layer 230, and the air-wing 875 creates an air-gap 876 (open on one side) beneath the air-wing 875 and the monolithic piezoelectric layer 230. The air-gaps 874 and 876 together surround the outside perimeter of the second electrode 840.

The outer frame 860 has inner edges that define a boundary of an active region 808 formed within the main membrane region 802. As should be appreciated by one skilled in the art, the outer frame 860 forms an effective Low Velocity Frame, and the region between the outer edge of inner frame 850 and inner edge of outer frame 860 forms an effective High Velocity Frame discussed above. The outer edges of the outer frame 860 define the outer edges of the main membrane region 802. The outer edges of the outer frame 860 also may coincide with the inner edges of the air-ring 870. Although not shown, a passivation layer may be present on top of second electrode 840, the inner frame 850, the outer frame 860 and the air-ring 870 (in each embodiment discussed herein) with a thickness sufficient to insulate all layers of the acoustic stack from the environment, including protection from moisture, corrosives, contaminants, debris and the like.

Although the air-ring 870, and corresponding air-gaps 874 and 876, are shown with rectangular shaped cross-sections, these structures may have other shapes, such as trapezoidal cross-sectional shapes, without departing from the scope of the present teachings. Examples of configurations, dimensions, alternative shapes, and the like with regard to air-bridges and/or air-wings are described and illustrated in U.S. Patent Application Publication No. 2012/0218057 (published Aug. 30, 2012) to Burak et al., U.S. Patent Application Publication No. 2010/0327697 (published Dec. 30, 2010) to Choy et al.; and U.S. Patent Application Publication No. 2010/0327994 (published Dec. 30, 2010) to Choy et al., the disclosures of which are hereby incorporated by reference in their entireties.

In certain embodiments, the air-ring 870 extends over the cavity 215 by an overlap (also referred to as decoupling region), determining separation of the outer edge of the main membrane region 802 from the substrate 810 edge. Also, the air-bridge 873 extends over the monolithic piezoelectric layer 230 by an air-bridge extension. The decoupling region has a width (x-dimension) of approximately 0.0 μm (i.e., no overlap with the cavity 215) to approximately 10.0 μm. Notably, the width of the decoupling region in FIGS. 8A and 8B is 0 μm, while in a typical BAW resonator, the target width of the decoupling region is about 2.0 μm, for example. The air-bridge extension region has a width of approximately 0.0 μm (i.e., no air-bridge) to approximately 50.0 μm, for example.

Referring to FIG. 8B, the BAW resonator device 800B includes substrate 210 defining air cavity 215, first (bottom) electrode 220 disposed on the substrate 210 and air cavity 215, planarization layer 222 disposed adjacent to first electrode 220 on the substrate 210, a seed layer 325 disposed on the first electrode 220 and the planarization layer 222, a split piezoelectric layer 330 disposed on the seed layer 325, and a second (top) electrode 840 disposed on the split piezoelectric layer 330. The split piezoelectric layer 330 includes a metal interposer 333 embedded within the split piezoelectric layer 330, effectively separating the split piezoelectric layer 330 into first and second portions 331 and 332. Collectively, the first electrode 220, the split piezoelectric layer 330, and the second electrode 840 constitute an acoustic stack of the BAW resonator device 800B. Also, an overlap among the first electrode 220, the split piezoelectric layer 330 and the second electrode 840 over the air cavity 215 defines a main membrane region 802 of the BAW resonator device 800B. Here, an overlap means the region where the first electrode 220, the split piezoelectric layer 330 and the second electrode 840 are mechanically attached to each other in vertical direction. In the depicted example, the outer edges of the second electrode 840 correspond to the inner edges of air-gap 874 and air-gap 876, defined by the air-bridge 873 and the air-wing 875, respectively (as discussed below), even though the air-bridge 873 and the air-wing 875 may be integral with the second electrode 840.

In the depicted embodiment, the metal interposer 333 is patterned in such a way that it is substantially confined to the main membrane region 802. Such patterning reduces or prevents parasitic transducer effect from occurring in the region where the metal interposer 333, the first portion 331, the first electrode 220 and the substrate 210 overlap. As would be appreciated by one skilled in the art, such patterning may be beneficial for structures with thicker metal interposers, where the voltage drop along the metal interposer 333 in the direction away from the main membrane region 802 may be negligible. However, patterning of the metal interposer 333 may increase the fabrication complexity and cost, and may also somewhat degrade quality of the second portion 332 at the outer edge of the metal interposer 333. Thus, in alternative embodiments, the metal interposer 333 may be patterned to extend outside the main membrane region 802. Or, the metal interposer 333 may not be patterned at all, in which case the metal interposer 333 would extend the entire width of the first portion 321 of the split piezoelectric layer 330 (non-embedded metal interposer), as shown for example in FIG. 8C. The advantages and disadvantages of patterning of the metal interposer 333 are considered from the overall cost/performance tradeoffs point of view. When patterning is used, it may provide unique benefits for particular situations and/or may allow application specific design requirements of various implementations to be met, as would be apparent to one skilled in the art.

As discussed above, the split piezoelectric layer 330 includes the metal interposer 333 dividing the split piezoelectric layer 330 into the first portion 331 and the second portion 332. The first portion 331 has a positive polarity directed substantially away from the first electrode 220 (indicated by upward pointing arrow 331′), where the positive polarity is enabled by the material of the seed layer 325 (e.g., aluminum oxynitride (ALON)), which flips the usual negative polarity of the AlN piezoelectric material. The second portion 332 has a negative polarity directed substantially toward the first electrode 220 (indicated by downward pointing arrow 332′), where the negative polarity is enabled by the material of the metal interposer 333 (e.g., molybdenum (Mo) or tungsten (W)), which flips the positive polarity of the AlN piezoelectric material to the usual negative polarity. The respective thicknesses (in the vertical direction shown in the orientation of FIG. 8B) of the first portion 331 and the second portion 332 differ relative to one another. The extent of this relative difference in thicknesses determines the coupling coefficient kt² of the BAW resonator device 800B, as discussed above.

In addition, the BAW resonator device 800B includes multiple lateral performance enhancement features, which increase the Q-factor, for example, associated with the second electrode 840. The performance enhancement features includes inner frame 850 formed in a center region on the second electrode 840, outer frame 860 formed in an outer region on the second electrode 840 (e.g., around an outer perimeter region of the second electrode 840), and air-ring 870 formed around an outer perimeter of the outer frame 860. The air-ring 870 is be formed between the monolithic piezoelectric layer 230 and the second electrode 840, such that it comprises an air-bridge 873 on a connection side of the second electrode 840 and an air-wing 875 along the remaining outside perimeter. The air-bridge 873 creates an enclosed air-gap 874 beneath the air-bridge 873 and the split piezoelectric layer 330, and the air-wing 875 creates an air-gap 876 (open on one side) beneath the air-wing 875 and the split piezoelectric layer 330. The air-gaps 874 and 876 together surround the outside perimeter of the second electrode 840. Further, details of the performance enhancement features are discussed above with reference to FIG. 8A, and will therefore not be repeated herein.

As discussed above, in alternative embodiments of the BAW resonator devices 800A, 800B and 800C, an acoustic mirror, such as a DBR (not shown), may be formed as the acoustic reflector in place of the cavity 215, without departing from the scope of the present teachings. The DBR may be formed on the top surface of the substrate 210, and may include one or more acoustic reflector layer pairs sequentially stacked on the substrate 210. Each of the stacked acoustic reflector layer pairs includes two layers, i.e., a first layer with a first acoustic impedance and a second layer with a second acoustic impedance stacked on the first layer. Within each acoustic reflector layer pair of the DBR, the first acoustic impedance is less than the second acoustic impedance.

Also, in alternative embodiments, the BAW resonator devices 800A and/or 800B with composite polarity piezoelectric layers may have fewer than all of the lateral enhancement features shown, without departing from the scope of the present teachings. For example, a BAW resonator device may have inner and/or outer frames, but no air-ring (i.e., no air-bridge and/or air-wing). Likewise, a BAW resonator device may have an air-ring, and no inner and/or outer frames.

In addition, the representative BAW resonator devices 200, 300, 800A and/or 800B may include a temperature compensating feature having a positive temperature coefficient for offsetting at least a portion of negative temperature coefficients elsewhere in the BAW resonator device. Temperature compensating features may include a temperature compensating layer in one or both of the first and second electrodes, for example. The temperature compensating layer may be formed of an oxide material, such as boron silicate glass (BSG), for example, having a positive temperature coefficient which offsets at least a portion of negative temperature coefficients of the monolithic piezoelectric layer or the split piezoelectric layer, and the conductive material in the top and bottom electrodes. As used herein, a material having a “positive temperature coefficient” means the material has positive temperature coefficient of elastic modulus over a certain temperature range. Similarly, a material having a “negative temperature coefficient” means the material has negative temperature coefficient of elastic modulus over the (same) certain temperature range. Various illustrative temperature compensating features are described by Burak et al., U.S. Patent App. Pub. No. 2014/0118092 (published May 1, 2014), which is hereby incorporated by reference in its entirety.

One of ordinary skill in the art would appreciate that many variations that are in accordance with the present teachings are possible and remain within the scope of the appended claims. These and other variations would become clear to one of ordinary skill in the art after inspection of the specification, drawings and claims herein. The invention therefore is not to be restricted except within the spirit and scope of the appended claims.

1. A bulk acoustic wave (BAW) resonator device, comprising:
a bottom electrode disposed over a substrate and an acoustic reflector;
a monolithic piezoelectric layer disposed over the bottom electrode, the piezoelectric layer comprising a first portion having a negative polarity and a second portion having a positive polarity that is substantially opposite to the negative polarity of the first portion with no discernible interface between the first and second portions; and
a top electrode disposed over the second portion of the monolithic piezoelectric layer,
wherein the first portion of the monolithic piezoelectric layer has a first thickness and the second portion of the monolithic piezoelectric layer has a second thickness that is not equal to the first thickness, thereby lowering a coupling coefficient kt² of the BAW resonator device while maintaining a combined thickness of the bottom electrode, the monolithic piezoelectric layer and the top electrode.

2. The BAW resonator device of claim 1, further comprising:
a temperature compensating feature having positive temperature coefficient for offsetting at least a portion of a negative temperature coefficient of at least the monolithic piezoelectric layer.

3. The BAW resonator device of claim 2, wherein the temperature compensating feature comprises a temperature compensating layer in one of the bottom electrode or the top electrode.

4. The BAW resonator device of claim 1, wherein the coupling coefficient kt² of the BAW resonator device varies proportionately with respect to a ratio of the first thickness to the second thickness.

5. The BAW resonator device of claim 1, further comprising:
at least one performance enhancement feature associated with the top electrode.

6. The BAW resonator device of claim 5, wherein the at least one performance enhancement feature comprises an outer frame formed in an outer region of the top electrode, the outer frame having an inner edge that defines an active region of the BAW resonator device.

7. The BAW resonator device of claim 6, wherein the at least one performance enhancement feature further comprises an inner frame formed in a center region of the BAW resonator device.

8. The BAW resonator device of claim 6, wherein the at least one performance enhancement feature further comprises an air-ring, formed outside an outer boundary of a main membrane region of the BAW resonator device and extending along at least a portion of an outer perimeter of the BAW resonator device.

9. The BAW resonator device of claim 8, wherein the air-ring is formed between the monolithic piezoelectric layer and the top electrode.

10. The BAW resonator device of claim 1, wherein the acoustic reflector is one of an air cavity or a distributed Bragg reflector (DBR).

11. A bulk acoustic wave (BAW) resonator device, comprising:
a bottom electrode disposed over a substrate and an acoustic reflector;
a seed layer disposed over the bottom electrode;
a split piezoelectric layer disposed on the seed layer, the split piezoelectric layer comprising a first portion having a positive polarity due to the seed layer, a second portion having a negative polarity that is substantially opposite to the positive polarity of the first portion, and a metal interposer between the first portion and the second portion; and
a top electrode disposed over the second portion the metal interposer of the split piezoelectric layer,
wherein the first portion of the piezoelectric layer has a first thickness and the second portion of the piezoelectric layer has a second thickness that is not equal to the first thickness, thereby lowering a coupling coefficient kt² of the BAW resonator device.

12. The BAW resonator device of claim 11, wherein the metal interposer is embedded in the split piezoelectric layer, such that the metal interposer has been patterned to be substantially confined to a main membrane region of the BAW resonator device.

13. The BAW resonator device of claim 11, wherein the metal interposer is extends an entire width of the first portion of the split piezoelectric layer, thereby separating the first and second portions of the split piezoelectric layer.

14. The BAW resonator device of claim 11, wherein the coupling coefficient kt² of the BAW resonator device varies proportionately with respect to a ratio of the first thickness to the second thickness.

15. The BAW resonator device of claim 11, wherein the first and second portions of the split piezoelectric layer are formed of aluminum nitride (AlN), and the dielectric material of the seed layer is formed of aluminum oxynitride (AlON).

16. The BAW resonator device of claim 15, wherein the metal interposer is formed of one of molybdenum (Mo) or tungsten (W).

17. The BAW resonator device of claim 11, further comprising:
a temperature compensating feature having positive temperature coefficient for offsetting at least a portion of a negative temperature coefficient of at least the split piezoelectric layer.

18. The BAW resonator device of claim 12, further comprising:
at least one performance enhancement feature associated with the top electrode.

19. The BAW resonator device of claim 18, wherein the at least one performance enhancement feature comprises an outer frame formed in an outer region of the top electrode, the outer frame having an edge that defines an active region of the BAW resonator device.

20. The BAW resonator device of claim 18, wherein the at least one performance enhancement feature comprises an inner frame formed in a center region of the BAW resonator device, and an air-ring, formed outside an outer boundary of a main membrane region of the BAW resonator device and extending along at least a portion of an outer perimeter of the BAW resonator device.
